(19) United States
(12) Patent Application Publication
(10) Pub. No.: US 2004/0084713 A1
(43) Pub. Date: May 6, 2004

(54) Structure with composite floating gate by poly spacer in flash

(75) Inventor: Chia-Ta Hsieh, Tainan (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 10/283,826

(22) Filed: Oct. 30, 2002

(51) Int. Cl. H01L 29/788

(52) U.S. Cl. 257/315

(57) ABSTRACT

A composite floating gate structure in flash memory cells is disclosed. Parallel active regions separated by isolation regions that extend from the surface of a semiconductor region of a substrate into the semiconductor region. A gate dielectric layer is disposed over the active regions. Planar parts of composite floating gates are composed of a first conductive layer and are equally spaced along the active regions where they are disposed over the gate dielectric layer. Spacer like parts of composite floating gates are composed of a second conductive layer and are disposed over the planar parts along both edges of edges planar parts so that sidewalls of the spacer like parts are parallel to the active regions. The spacer like parts and the planar parts compose the composite floating gates. An interlevel dielectric layer is patterned into equally spaced parallel stripes perpendicular to the active regions and each stripe is disposed over the corresponding composite floating gate for each active region. Word lines, which are composed of a third conductive layer, are parallel lines disposed over the interlevel dielectric layer and serve as control gates.

### BACKGROUND OF THE INVENTION

(1) Field of the Invention

The present invention relates generally to semiconductor integrated circuit technology and more particularly to memory cells used in flash EEPROMs (Electrically Erasable Programmable Read Only Memory).

(2) Description of Prior Art

The efficiency of program operation in flash memory cells is dependent on the coupling ratio between a control gate and a floating gate. In flash memory cells a gate dielectric layer formed over a semiconductor region separates a floating gate from the semiconductor region. Charge is exchanged between the floating gate and the semiconductor region through the gate dielectric layer and the charging and discharging of the floating gate in this way constitute the programming and erasing operations. A control gate is separated from the floating gate by an interlevel dielectric so that the control gate is capacitively coupled to the floating gate and this coupling is utilized to control the voltage dropped across the gate dielectric. Direct exchange of charge between the control gate and floating gate is to be avoided. The coupling ratio is essentially the ratio of the voltage drop across the gate dielectric to the voltage drop across the interlevel dielectric. It is clearly advantageous to have as much of the applied potential as possible across the floating gate to semiconductor region dielectric thereby enhancing the efficiency of the programming and erase operations. Larger coupling ratios are thus more desirable. Since the ratio of the voltage drop across the gate dielectric to the voltage drop across the interlevel dielectric is equal to the inverse of the ratio of the capacitances across these layer it is beneficial to have the control gate-floating gate capacitance as large, and the floating gate-semiconductor region capacitance as small, as is practical. This must take into account that if charge is to pass through the gate dielectric it cannot be too thick and if charge is not to pass through the interlevel dielectric it cannot be too thin. These constraints hinder the setting of the thickness of the dielectric layers to achieve high coupling ratios. In traditional flash memory cells, where the areas of the control gate-floating gate capacitor and the floating gate-semiconductor region capacitor are comparable and low coupling ratios are compensated by increased applied voltage. However, increased voltage can give rise to reliability problems. Also, high voltage could require excessive circuitry, which uses valuable cell area and impedes the ability of shrinking the cell.

In the present invention a structure is disclosed in which the coupling ratio is increased by substantially increasing the area of the control gate-floating gate capacitor so that its area is much larger then the area of the floating gate-semiconductor region capacitor. This is accomplished in a method, which is an integral part of the invention, that utilizes a novel application of the spacer etch technique. By deviating from the traditional planer stacking structure, the increase of the control gate-floating gate capacitor area is accomplished without any increase in cell size. With a high coupling ratio resulting from the increased area of the control gate-floating gate capacitor the thickness of the dielectric layers can be maintained as they optimally should be, the gate dielectric layer relatively thin and the interlevel dielectric layer relatively thick. In addition, the applied voltage can be low with resulting improved reliability and reduced circuitry.

Hsieh et al. U.S. Pat. No. 6,312,989 disclose a split gate flash with protruding source that contains a spacer control gate. Hsieh et al. U.S. Pat. No. 6,297,099 disclose a flash with a floating gate process. U.S. Pat. No. 6,249,454 to Sung et al. shows a split gate flash memory cell. U.S. Pat. No. 6,207,503 disclose a method for shrinking array dimensions of split gate flash memory cells that utilizes spacer processes.

### SUMMARY OF THE INVENTION

It is a primary objective of the invention to provide floating gate and control gate structures in flash memory cells with increased control gate to floating gate coupling ratio. Another primary objective of the invention is to provide floating gate and control gate structures in flash memory cells with increased control gate to floating gate coupling ratio that is achieved without increase of cell size. It is another primary objective of the invention to provide floating gate and control gate structures in flash memory cells that require lower control gate applied voltage and thus possess increased reliability. Yet another primary objective is to provide floating gate and control gate structures in flash memory cells whose decrease in cell size is not limited by the circuitry required to deliver the high voltage needed for traditional programming and erasing processes. It is yet another primary objective of the invention to provide a method to fabricate floating gate and control gate structures in flash memory cells with increased control gate to floating gate coupling ratio. It is yet another primary objective of the invention to provide a method to fabricate floating gate and control gate structures in flash memory cells with increased control gate to floating gate coupling ratio that is achieved without increase of cell size. It is yet another primary objective of the invention to provide a method to fabricate floating gate and control gate structures resulting in flash memory cells that require lower top gate voltage and thus possesses increased reliability. Yet another primary objective is to provide a method to fabricate floating gate and control gate structures resulting in flash memory cells whose cell decrease is not limited by the circuitry required to deliver the high voltage needed for traditional programming and erasing processes.

These objectives are achieved in the invention by floating gate and control gate structures that deviate from the planar structures of traditional flash memory cells. In preferred embodiments of the invention the floating gate is a composite structure. A spacer like part of a composite floating gate is formed on a planar part, the parts being in intimate electrical contact. The planar bottom surface of the composite floating gate is disposed over a gate dielectric layer formed over a planar surface of a semiconductor region. An interlevel dielectric layer is disposed over the exposed upper surface of both the spacer like and planar parts of the composite floating gate and the control gate is formed over the interlevel dielectric layer. The area of the vertical sidewalls of the spacer like part of the composite floating gate can be very much larger than the area of the planar part resulting in a significant increase of the coupling ratio over that of conventional structures and, since the spacer like part does not extend horizontally beyond the planar part, the increased area is achieved with no expenditure of cell area. With all increased coupling ratio applied voltages can be lower with a consequential improvement in reliability and with no need for circuitry to support high voltage.

A composite floating gate structure in flash memory cells is disclosed. Parallel active regions separated by isolation regions that extend from the surface of a semiconductor region of a substrate into the semiconductor region. A gate dielectric layer is disposed over the active regions. Planar parts of composite floating gates are composed of a first conductive layer and are equally spaced along the active regions where they are disposed over the gate dielectric layer. Spacer like parts of composite floating gates are composed of a second conductive layer and are disposed over the planar parts along both edges of edges planar parts so that sidewalls of the spacer like parts are parallel to the active regions. The spacer like parts and the planar parts compose the composite floating gates. An interlevel dielectric layer is patterned into equally spaced parallel stripes perpendicular to the active regions and each stripe is disposed over the corresponding composite floating gate for each active region. Word lines, which are composed of a third conductive layer, are parallel lines disposed over the interlevel dielectric layer and serve as control gates.

### BRIEF DESCRIPTION OF THE DRAWINGS

In the accompanying drawing forming a material part of this description, there is shown:

FIGS. 1a-1f show top views depicting a method of forming floating gate and control gate structures, according to the invention, in flash memory cells.

FIGS. 2a-2f show cross-sectional views depicting a method of forming floating gate and control gate structures, according to the invention, in flash memory cells.

### DESCRIPTION OF THE PREFERRED EMBODIMENTS

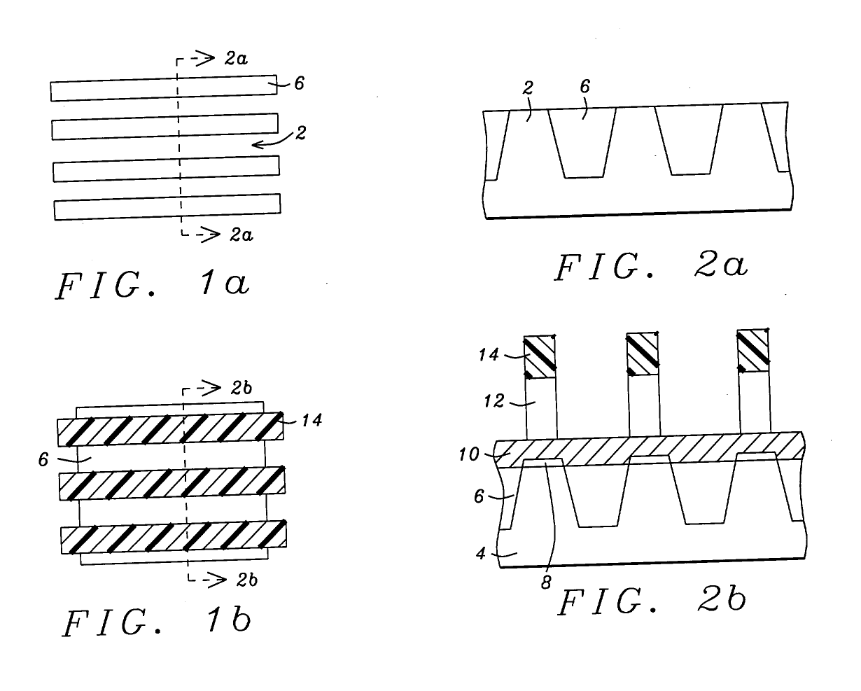

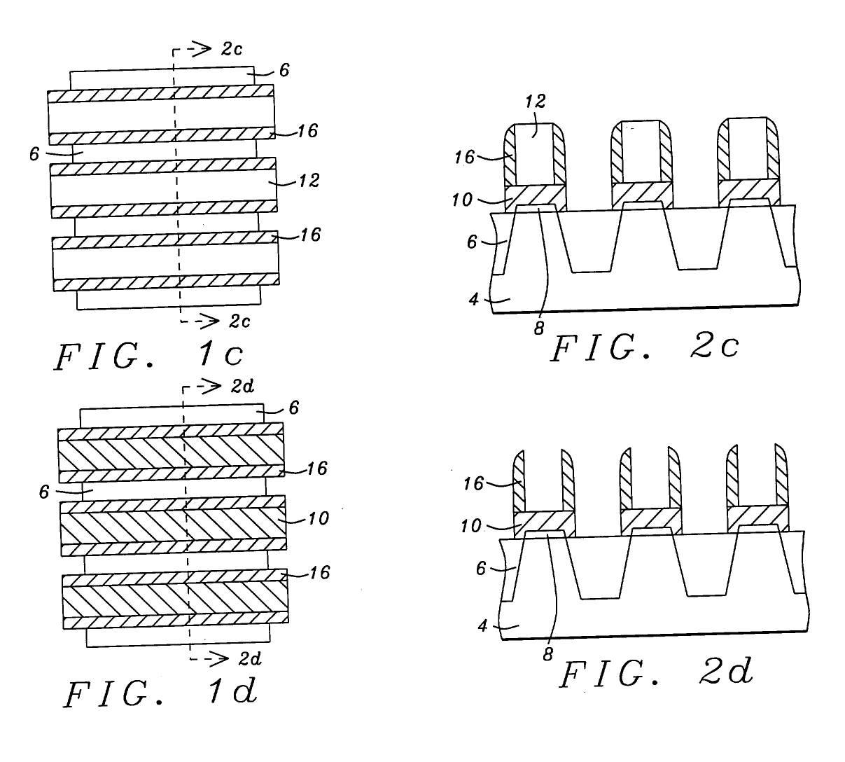

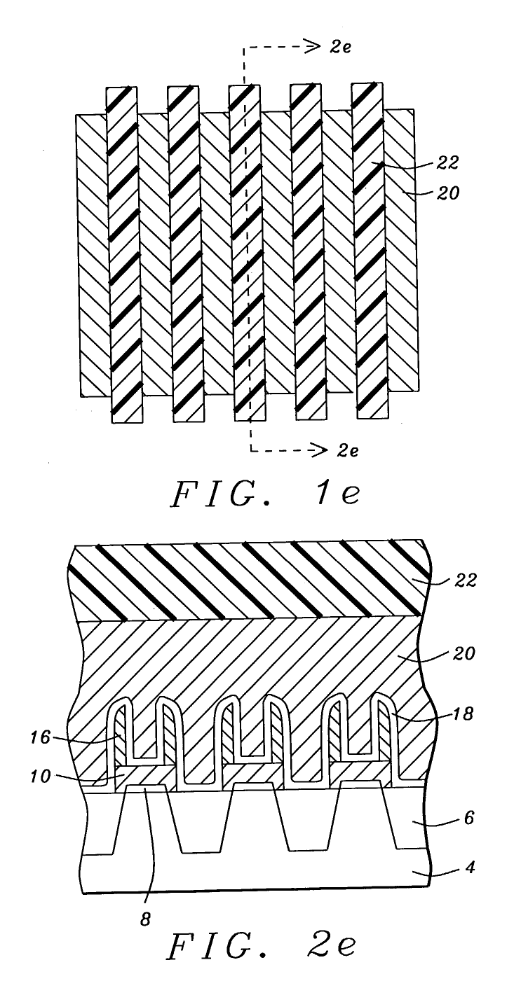

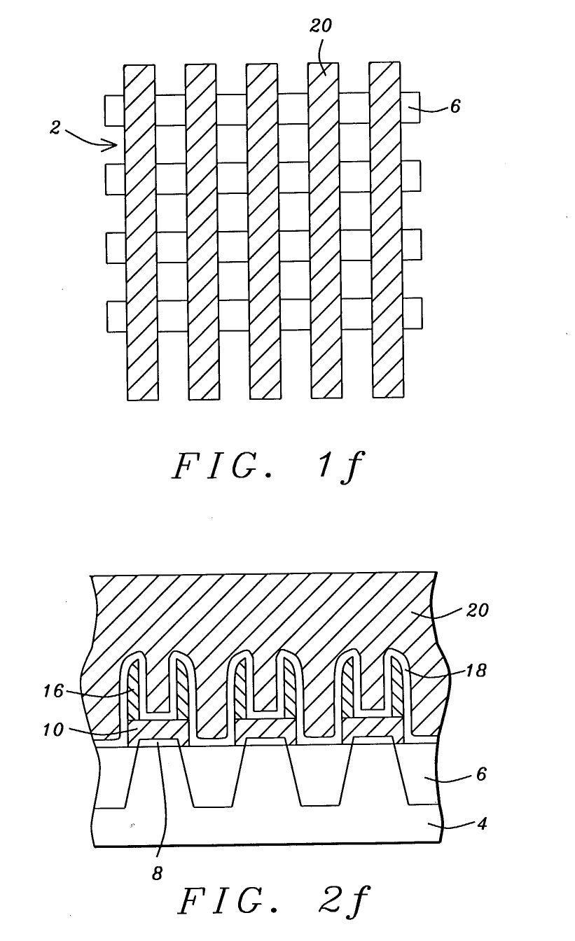

Preferred embodiments of the invention are well described with the aid of FIGS. 1a-1f and 2a-2f. A method of fabricating a composite floating gate and control gate is presented in FIGS. 1a-1f, where top views are presented at successive stages of the process and in FIGS. 2a-2f, which show the corresponding cross-sectional views. As shown in FIGS. 1a and 2a, active regions, 2, are defined on a semiconductor region, 4, which preferably is a p-type silicon region, using isolation regions, such as shallow trench isolation, STI, regions, 6. A floating gate dielectric layer, 8, is then formed over the active regions to a thickness of about 100 Angstroms. Preferably the floating gate dielectric layer is a thermally grown oxide. The gate dielectric layer serves as the dielectric layer between the semiconductor region and the floating gate. Deposition of a first conductive layer, 10, follows, which will be fashioned in forthcoming process steps to form the planar part of the composite floating gate of the invention. Preferably the first conductive layer is a first polysilicon layer deposited to a depth of about 300 Angstroms. An insulator layer is then formed that is preferably a nitride layer of depth about 1500 Angstroms. This insulator layer is patterned into stripes, 12, disposed over the active regions, as shown in FIGS. 1b and 2b. The patterning of the insulating layer is preferably accomplished by forming a photoresist layer, patterning the photoresist to define the stripe pattern, etching the insulator layer, stopping at the first conductive layer and removing the photoresist layer. A second conductive layer is deposited from which will be fashioned the spacer like part of the composite floating gate of the invention. Preferably the second conductive layer is a second polysilicon layer deposited to a depth of about 600 Angstroms. A spacer etch is performed to remove all of the second conductive layer except for region 16 along the sidewalls of the insulator layer stripes, 14. The etching period is extended so that first conductive layer not under the insulator layer stripes or remaining second conductive layer is also removed. The structure at this point of the process is shown in FIGS. 1c and 2c. After removal of the insulator layer stripes, 14, which can be done, for example, with an H₃PO₄ wet etch, the spacer like part of the composite floating gate structure is apparent as shown in FIGS. 1d and 2d. An interlevel dielectric layer, 18, is now formed that serves as the dielectric layer between the floating gate and a control gate to be subsequently formed. The interlevel dielectric layer is preferably an ONO layer with the depths of the layers being about 50, 100 and 20 Angstroms, for the bottom oxide, nitride and upper oxide layers, respectively. A third conductive layer, 20, is deposited that preferably is a third polysilicon layer deposited to a depth of about 2000 Angstroms. The third conductive layer is patterned to serve as control gates and as parallel word lines running perpendicular to the active regions, as shown in FIGS. 1f and 2f. Forming a photoresist layer, 22, patterning the photoresist layer, as shown in FIGS. 1e and 2e, and etching the third conductive layer can, for example, accomplish this patterning. Before removing the patterned photoresist, the exposed interlevel dielectric layer, second conductive layer and first conductive layer are etched. Thus none of the interlevel dielectric layer, second conductive layer and First conductive layer remains except that which is disposed under the third conductive layer lines. This completes the fabrication of the composite floating gate and control gate according to most preferred embodiments of the invention.

The objectives of the invention are achieved by floating gate and control gate structures that deviate from the planar structures of traditional flash memory cells. In preferred embodiments of the invention the floating gate is a composite structure. A spacer like part of a composite floating gate is formed on a planar part, the parts being in intimate electrical contact. The planar bottom surface of the composite floating gate is disposed over a gate dielectric layer formed over a planar surface of a semiconductor region. An interlevel dielectric layer is disposed over the exposed upper surface of both the spacer like and planar parts of the composite floating gate and the control gate is formed over the interlevel dielectric layer. The area of the vertical sidewalls of the spacer like part of the composite floating gate can be very much larger than the area of the planar part resulting in a significant increase of the coupling ratio over that of conventional structures and, since the spacer like part does not extend horizontally beyond the planar part, the increased area is achieved with no expenditure of cell area. With an increased coupling ratio applied voltages can be lower with a consequential improvement in reliability and with no need for circuitry to support high voltage

Referring to FIG. 2f, the increased control gate to floating gate coupling ratio achieved for preferred embodiments of the invention is apparent. This coupling ratio is the ratio of the voltage drop across the gate dielectric layer, 8, to the voltage drop across the interlevel dielectric layer, 18, which is also the ratio of the capacitance of the control gate to floating gate capacitor to the capacitance of the floating gate to semiconductor region. The factor by which the coupling ratio for the structure of the invention is increased over that of the traditional structure, where capacitance areas are equal, is given by the ratio of the capacitor areas. As can be seen from FIG. 2f the area ratio is close to 1+(4 h/x), where h, 24, is the height of the spacer like portion of the composite floating gate of the invention and x, 26, is the width of the active region. Thus, the larger is h the larger is the increase in coupling ratio and the smaller is x the larger is the increase in coupling ratio. As feature sizes decrease, that is as x decreases, composite floating gate structures of the invention of the same height, h, will give rise to greater increase in the coupling ratio. For example, for x=1 micron and h=1500 Angstrom, the area ratio is 1.6, while for x=0.5 micron and h=1500 Angstrom the area ratio is 2.1. So that for 1 micron technology the coupling ratio of a typical composite floating gate structure of the invention is a factor of 1.6 times greater than a traditional floating structure, for 0.5 micron technology the factor is 2.1.

While the invention has been particularly shown and described with reference to the preferred embodiments thereof, it will be understood by those skilled in the art that various changes in form and detail may be made without departing from the spirit and scope of the invention.

What is claimed is:

1. A composite floating gate structure in flash memory cells comprising:
a semiconductor region within a substrate extending to a surface;
parallel active regions separated by isolation regions that extend from said surface into said semiconductor region;
a gate dielectric layer disposed over said active regions;
planar parts of composite floating gates that are composed of a first conductive layer and that are equally spaced along said active regions where they are disposed over said gate dielectric layer;
spacer like parts of composite floating gates that are composed of a second conductive layer and that are disposed over said planar parts along both edges of said planar parts so that sidewalls of said spacer like parts are parallel to said active regions, and which together with the planar parts compose said composite floating gates;
an interlevel dielectric layer that constitutes equally spaced parallel stripes perpendicular to said active regions, where each said stripe is disposed over a corresponding composite floating gate for each active region;
word lines, which are composed of a third conductive layer, that are parallel lines disposed over said interlevel dielectric layer and that serve as control gates.

2. The structure of claim 1 wherein said semiconductor region is a silicon region.

3. The structure of claim 1 wherein said isolation regions are shallow trench isolation regions.

4. The structure of claim 1 wherein said gate dielectric layer is an oxide layer.

5. The structure of claim 1 wherein said gate dielectric layer is a thermally grown oxide layer of thickness about 100 Angstroms.

6. The structure of claim 1 wherein said first conductive layer is a polysilicon layer deposited to a thickness of about 300 Angstroms.

7. The structure of claim 1 wherein said insulator layer is a nitride layer of thickness about 1500 Angstroms.

8. The structure of claim 1 wherein said second conductive layer is a polysilicon layer deposited to a thickness of about 600 Angstroms.

9. The structure of claim 1 wherein said interlevel dielectric layer is a composite dielectric layer.

10. The structure of claim 1 wherein said interlevel dielectric layer is an ONO layer with the thickness of the bottom oxide layer, nitride layer and top oxide layer are about 50, about 100 and about 20 Angstroms, respectively.

11. The structure of claim 1 wherein said third conductive layer is a polysilicon layer deposited to a thickness of about 2000 Angstroms.

12. A method of Fabricating a composite floating gate structure in flash memory cells comprising:
providing a semiconductor region within a substrate extending to a surface containing parallel active regions separated by isolation regions that extend from said surface into said semiconductor region;
forming a gate dielectric layer over said active regions;
forming a blanket first conductive layer over said active regions and said isolation regions;
forming an insulator layer and patterning said insulator layer into stripes disposed over said active regions;
forming a second conductive layer and performing a spacer etch on said second conductive layer to second conductive layer spacers disposed against the sidewalls of said insulator layer and over said first conducting layer;
removing said first conductive layer that is not under said insulator layer or said second conductive layer spacers;
removing said insulator layer;
removing a blanket interlevel dielectric layer;
forming a blanket third conductive layer and patterning said third conductive layer into parallel lines perpendicular to said active regions
removing said interlevel dielectric layer, said second conductive layer and first conductive layer that is not under said third conductive layer lines.

13. The method of claim 12 wherein said semiconductor region is a silicon region.

14. The method of claim 12 wherein said isolation regions are shallow trench isolation regions.

15. The method of claim 12 wherein said gate dielectric layer is an oxide layer.

16. The method of claim 12 wherein said gate dielectric layer is a thermally grown oxide layer of thickness about 100 Angstroms.

17. The method of claim 12 wherein said first conductive layer is a polysilicon layer deposited to a thickness of about 300 Angstroms.

18. The method of claim 12 wherein said insulator layer is a nitride layer of thickness about 1500 Angstroms.

19. The method of claim 12 wherein said patterning of said insulator layer is accomplished by forming a first photoresist layer, patterning said first photoresist layer and etching exposed insulator layer.

20. The method of claim 12 wherein said second conductive layer is a polysilicon layer deposited to a thickness of about 600 Angstroms.

21. The method of claim 12 wherein said interlevel dielectric layer is a composite dielectric layer.

22. The method of claim 12 wherein said interlevel dielectric layer is an ONO layer with the thickness of the bottom oxide layer, nitride layer and top oxide layer are about 50, about 100 and about 20 Angstroms, respectively.

23. The method of claim 12 wherein said third conductive layer is a polysilicon layer deposited to a thickness of about 2000 Angstroms.

24. The method of claim 12 wherein said patterning of said third conductive layer into parallel lines perpendicular to said active regions and said removal of said interlevel dielectric layer, said second conductive layer and first conductive layer that is not under said third conductive layer lines is accomplished by forming a photoresist layer, patterning the photoresist layer and sequentially etching the third conductive layer, the interlevel dielectric layer, second conductive layer and first conductive layer.
